(19) United States
(12) Patent Application Publication
(10) Pub. No.: US 2013/0187257 A1
(43) Pub. Date: Jul. 25, 2013

(54) Semiconductor device and method for manufacturing the same

(71) Applicants: Du Jian, Wuxi (CN); Li Jiajia, Wuxi (CN); Fang Hao, Wuxi (CN)

(72) Inventors: Du Jian, Wuxi (CN); Li Jiajia, Wuxi (CN); Fang Hao, Wuxi (CN)

(73) Assignees: CSMC TECHNOLOGIES FAB2 CO., LTD., Wuxi, Jiangsu (CN); CSMC TECHOLOGIES FAB1 CO., LTD., Wuxi, Jiangsu (CN)

(21) Appl. No.: 13/825,505

(22) PCT Filed: Nov. 18, 2011
(86) PCT No.: PCT/CN2011/082400

§ 371 Date: Mar. 21, 2013

(30) Foreign Application Priority Data
Nov. 29, 2010 (CN) 201010564110.2

(51) Int. Cl. H01L 23/29; H01L 21/265

(52) U.S. Cl. CPC H01L 23/291; H01L 21/265
USPC 257/607; 438/514

(57) ABSTRACT

A method is disclosed for manufacturing a semiconductor device. The method includes providing a substrate and forming a well region in the substrate by an ion implantation. The method also includes forming, by rapid thermal oxidation and on the substrate having the well region, an oxide layer for repairing the substrate damaged by the ion implantation. Further, the method includes removing the oxide layer and forming a gate oxide layer on the repaired substrate having the well region.

### FIELD OF THE INVENTION

The present invention generally relates to the field of semiconductor manufacturing and, more particularly, to semiconductor devices and methods and processes for manufacturing the same.

### BACKGROUND

With continuous progresses in Integrated Circuit (IC) manufacturing techniques and tools, the level of integration of ICs has become increasingly higher, which requires further scaling down on the sizes of the semiconductor devices. The decrease in their sizes often leads to the occurrence of the short-channel effect. The short-channel effect is an effect whereby a device with a reduced channel length has an increased possibility of punchthrough of its source and drain, causing undesired leakage current.

In order to avoid the short-channel effect, a Super-Steep Retrograde Channel (SSRC) is formed by well region implantation. The process of forming the SSRC generally includes forming a P-well by implanting indium ions, and forming an N-well by implanting arsenic ions. Indium ions are relatively heavy, and the silicon substrate may be damaged by the implanted indium ions during the formation of the P-well. The damaged silicon substrate may further affect the subsequent gate oxide layer, i.e., causing weak spots on the gate oxide layer. The weak spots may accelerate the breakdown of the gate oxide layer and, therefore, reduce the reliability of the gate oxide layer.

In order to improve the reliability of the gate oxide layer, some companies use an implantation dose of less than 1×10¹³cm⁻² indium ions to prevent the silicon substrate from being damaged by a massive dose of indium ions. However, when the size of the semiconductor device continues to shrink, the implantation dose of indium ions has to be continuously increased to meet other performance requirements of the semiconductor device.

The disclosed methods and systems are directed to solve one or more problems set forth above and other problems.

### BRIEF SUMMARY OF THE DISCLOSURE

One aspect of the present disclosure includes a method for manufacturing a semiconductor device. The method includes providing a substrate and forming a well region in the substrate by an ion implantation. The method also includes forming, by rapid thermal oxidation and on the substrate having the well region, an oxide layer for repairing the substrate damaged by the ion implantation. Further, the method includes removing the oxide layer and forming a gate oxide layer on the repaired substrate having the well region.

Another aspect of the present disclosure includes a semiconductor device. The semiconductor device includes a substrate and a well region in the substrate formed by an ion implantation. The semiconductor device also includes a gate oxide layer on the substrate. The gate oxide layer is formed by forming, by rapid thermal oxidation and on the substrate having the well region, an oxide layer for repairing the substrate damaged by the ion implantation, removing the oxide layer, and forming a gate oxide layer on the repaired substrate having the well region.

Other aspects of the present disclosure can be understood by those skilled in the art in light of the description, the claims, and the drawings of the present disclosure.

### BRIEF DESCRIPTION OF THE DRAWINGS

FIG. 1 illustrates an exemplary flow chart of a method for manufacturing a semiconductor device consistent with the disclosed embodiments;

FIG. 2 illustrates an exemplary flow chart another method for manufacturing a semiconductor device consistent with the disclosed embodiments; and

FIG. 3 to FIG. 9 are cross-section views of a semiconductor device during a manufacturing process consistent with the disclosed embodiments.

### DETAILED DESCRIPTION

Reference will now be made in detail to exemplary embodiments of the invention, which are illustrated in the accompanying drawings. Wherever possible, the same reference numbers will be used throughout the drawings to refer to the same or like parts.

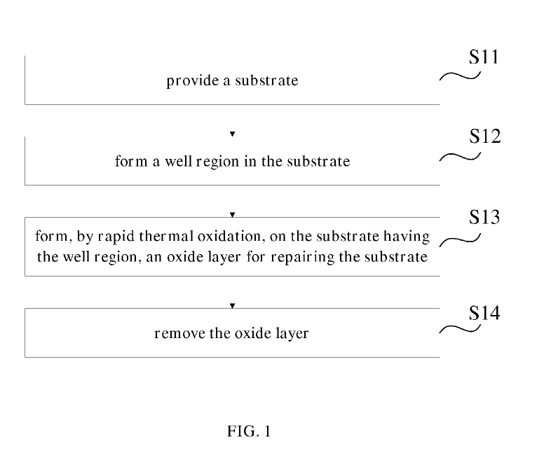

FIG. 1 illustrates an exemplary flow chart of a method for manufacturing a semiconductor device consistent with the disclosed embodiments . As shown in FIG. 1, at the beginning, a substrate is provided (S11).

The substrate may include any appropriate material for making double-gate structures. For example, the substrate may include a semiconductor structure, e.g., silicon, silicon germanium (SiGe) with a monocrystalline, polycrystalline, or amorphous structure. The substrate may also include a hybrid semiconductor structure, e.g., carborundum, indium antimonide, lead telluride, indium arsenide, indium phosphide, gallium arsenide or gallium antimonide, alloy semiconductor, or a combination thereof. Further, the substrate may include a silicon-on-insulator (SOI) structure. In addition, the substrate may also include other materials, such as a multi-layered structure of epitaxial layer or buried layer. In certain embodiments, the substrate may be a silicon substrate, which may also be referred to as a silicon base.

After the substrate is provided (S11), a well region is formed in the substrate (S12). It should be noted that ‘in the substrate’ and ‘on the substrate’ refer to two different concepts. Specifically, the term ‘in the substrate’ refers to an area ranging from the surface of the substrate to a certain depth, and the area is part of the substrate. On the other hand, the term ‘on the substrate’ refers to an area above the surface of the substrate, which is not part of the substrate itself.

The well region in the substrate may be formed by various processes. For example, the processes for forming the well region in the substrate may include: forming a photoresist layer with a well region pattern on the substrate; forming a well region in the substrate by ion implantation using the photoresist layer with the well region pattern as a mask; and removing the photoresist layer with the well region pattern.

In general, an N-well may be formed by implanting pentavalent ions, such as phosphorus and arsenic ions; and a P-well may be formed by implanting trivalent ions, such as boron and indium ions. If the implanted ions are relatively heavy (e.g., indium ions), the relatively heavy ions may cause damages to the substrate. In the conventional process, after the well region is formed, rapid thermal annealing (RTA) or similar process is performed. The rapid thermal annealing can activate the implanted ions, but cannot repair the damaged surface of the silicon substrate.

As shown in FIG. 1, after the well region is formed (S12), an oxide layer for repairing the substrate is formed by rapid thermal oxidation on the substrate having the well region (S13). That is, after the well region is formed in the substrate, instead of the conventional rapid thermal annealing, a rapid thermal oxidation process is performed to form an oxide layer on the substrate having the well region for repairing the substrate. The oxide layer may be formed by oxidizing the silicon substrate that is damaged during ion implantation. In certain embodiments, the oxide layer may be silicon oxide, and may have a thickness of about 100 Å.

Further, the oxide layer is removed (S14). That is, the oxide layer formed in S13 is washed away, which means that the damaged portion of the silicon substrate is removed and the undamaged portion of the substrate remain. In other words, the damaged substrate is repaired. Therefore, when the subsequent gate oxide layer is formed, it is no longer affected by the damaged substrate, and the reliability of the subsequent gate oxide layer can be improved.

FIG. 2 shows a flow chart of another method for manufacturing a semiconductor device with more details. As shown in FIG. 2, at the beginning, a substrate is provided (S21).

The provided substrate may include a body layer and an epitaxial layer. The body layer may be N-type monocrystalline silicon; and the epitaxial layer may be lightly-doped monocrystalline silicon grown on the N-type monocrystalline silicon. The epitaxial layer may have a crystal structure same as the body layer, with a higher purity and less crystallographic defects than the body layer. In certain other embodiments, the body layer may be germanium, indium phosphide, gallium arsenide or other semiconductor materials.

Although the substrate may include a body layer and an epitaxial layer, the body layer and the epitaxial layer are both referred as the substrate for the various manufacturing processes.

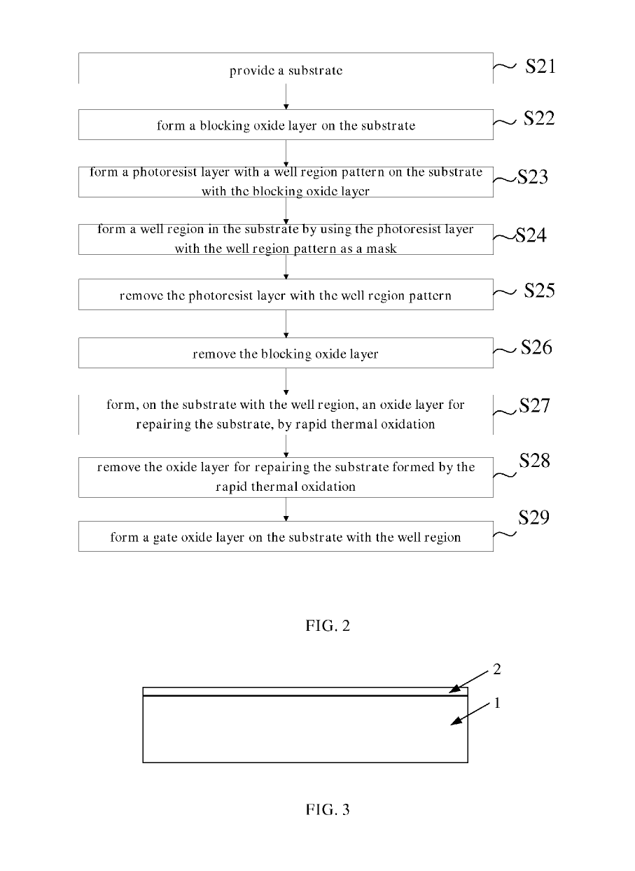

After the substrate is provided (S21), a blocking oxide layer is formed on the substrate (S22). FIG. 3 shows a corresponding semiconductor device after forming the blocking oxide layer.

As shown in FIG. 3, a blocking oxide layer 2 is formed on the substrate 1 by thermal oxidation. The blocking oxide layer 2 may be silicon oxide, and may have a thickness of about 150 Å. Because the blocking oxide layer 2 is to serve as a blocking layer in the well region implantation, the thickness of the blocking oxide layer 2 may be relatively small.

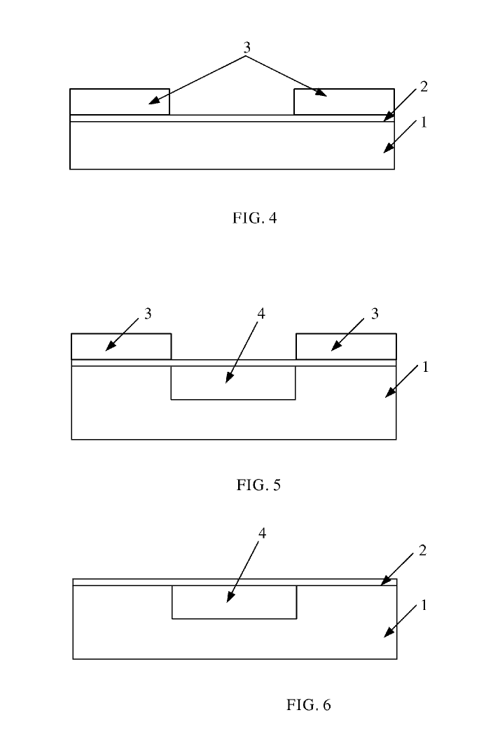

Further, a photoresist layer with a well region pattern is formed on the substrate having the blocking oxide layer (S23). FIG. 4 shows the corresponding semiconductor device after forming the photoresist layer.

As shown in FIG. 4, at first, photoresist is spin-coated on the substrate 1 having the blocking oxide layer 2. Then, the photoresist is exposed by using a corresponding mask plate. Further, after the exposure and developing, a photoresist layer 3 with the well region pattern is formed on the substrate 1 having the blocking oxide layer 2.

After forming the photoresist layer 3 (S23), a well region is formed in the substrate using the photoresist layer with the well region pattern as a mask (S24). FIG. 5 shows the corresponding semiconductor device after forming the well region.

As shown in FIG. 5, well region 4 is formed in the substrate 1 by ion implantation using the photoresist layer 3 with the well region pattern as a mask. The well region 4 formed in the substrate may be a P-well, and the implanted ions may be indium ions. Other type of well region and/or implantation ions may also be used. Further, the dose of the implanted indium ions may be approximately 1×10¹³cm⁻². Other doses higher than 1×10¹³cm⁻² may also be used.

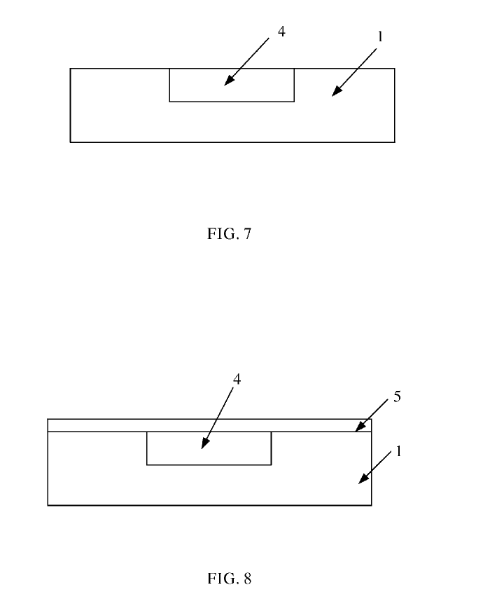

Further, the photoresist layer with the well region pattern is removed (S25). FIG. 6 shows the substrate 1 with well region 4 and blocking oxide layer 2 and without the photoresist layer 3. The blocking oxide layer is also removed (S26). FIG. 7 shows the substrate 1 with well region 4 and without blocking oxide layer 2.

After removing the blocking oxide layer 2 (S26), an oxide layer for repairing the substrate is formed by rapid thermal oxidation on the substrate having the well region (S27). FIG. 8 shows the corresponding semiconductor device after forming the oxide layer (i.e., the repairing oxide layer).

As shown in FIG. 8, an oxide layer 5 for repairing the substrate is formed on the substrate 1 having the well region 4. The oxide layer 5 may be formed by rapid thermal oxidation. That is, the oxide layer 5 may be formed by oxidizing the damaged substrate in an oxygen environment. The thickness of the formed oxide layer 5 may be controlled by controlling the time of the rapid thermal oxidation process. In certain embodiments, the thickness of the formed oxide layer 5 may be approximately 100 ÅA, and the oxide layer 5 may be silicon oxide.

Further, the oxide layer 5 for repairing the substrate is removed (S28). That is, after the substrate 1 is repaired, the repairing oxide layer 5 is removed. The corresponding semiconductor device after removing the oxide layer 5 is similar to that shown in FIG. 7 and is omitted.

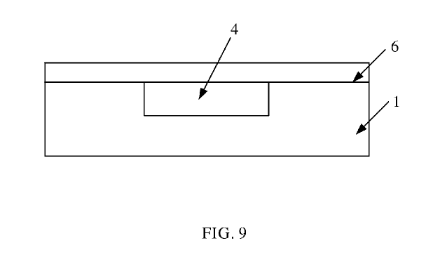

After removing the oxide layer formed by rapid thermal oxidation (S28), a gate oxide layer is formed on the substrate having the well region (S29). FIG. 9 shows the corresponding semiconductor device after forming the gate oxide layer.

As shown in FIG. 9, a gate oxide layer 6 is formed on the substrate 1 having the well region 4 by thermal oxidation. The gate oxide layer 6 may act as a dielectric between the gate and the source/drain of the semiconductor device. The thickness of the gate oxide layer 6 may be controlled by controlling the time of the thermal oxidation process, and the thickness of the gate oxide layer 6 may range from about 20 Å to hundreds of Å. In certain embodiments, the thickness of the gate oxide layer 6 may be 200 Å, and the gate oxide layer 6 may be silicon oxide.

After the gate oxide layer 6 is formed on the substrate 1 having the well region 4, performance tests can be performed on the gate oxide layer 6. Based on testing results, the probability of breakdown of the gate oxide layer is considerably reduced after the repairing process; hence the reliability of the gate oxide layer is significantly improved.

By using the disclosed methods and processes, the reliability of the gate oxide layer can improve without reducing the implantation dose of ions. More specifically, by using the disclosed methods and processes, the gate oxide layer is formed on the repaired substrate, thereby avoiding the occurrence of weak spots on the gate oxide layer, and significantly improving the reliability of the gate oxide layer.

It is understood that the disclosed embodiments may be applied to any semiconductor devices. Various alternations, modifications, or equivalents to the technical solutions of the disclosed embodiments can be obvious to those skilled in the art.

1. A method for manufacturing a semiconductor device, comprising:
providing a substrate;
forming a well region in the substrate by an ion implantation;
forming, by rapid thermal oxidation, on the substrate having the well region, an oxide layer for repairing the substrate damaged by the ion implantation;
removing the oxide layer; and
forming a gate oxide layer on the repaired substrate having the well region.

2. The method according to claim 1, wherein the oxide layer for repairing the substrate has a thickness of approximately 100 Å.

3. The method according to claim 1, wherein the well region formed in the substrate is a P-well.

4. The method according to claim 1, wherein the well region formed in the substrate is a P-well doped with indium ions.

5. The method according to claim 1, further including:
before forming the well region in the substrate, forming a blocking oxide layer on the substrate; and
after forming a well region in the substrate, removing the blocking oxide layer.

6. The method according to claim 1, wherein forming the well region in the substrate includes:
forming a photoresist layer with a well region pattern on the substrate;
forming the well region in the substrate using the photoresist layer with the well region pattern as a mask; and
removing the photoresist layer with the well region pattern.

7. The method according to claim 1, wherein the oxide layer for repairing the substrate is silicon oxide.

8. A semiconductor device, comprising:
a substrate;
a well region in the substrate formed by an ion implantation; and
a gate oxide layer on the substrate, wherein the gate oxide layer is formed by:
forming, by rapid thermal oxidation, on the substrate having the well region, an oxide layer for repairing the substrate damaged by the ion implantation;
removing the oxide layer; and
forming a gate oxide layer on the repaired substrate having the well region.

9. The semiconductor device according to claim 8, wherein the oxide layer for repairing the substrate is formed by rapid thermal oxidation.

10. The semiconductor device according to claim 8, wherein the well region in the substrate is a P-well doped with indium ions.

11. The semiconductor device according to claim 8, wherein the oxide layer for repairing the substrate has a thickness of approximately 100 Å.

12. The semiconductor device according to claim 8, wherein the well region in the substrate is formed by:
forming a photoresist layer with a well region pattern on the substrate;
forming the well region in the substrate using the photoresist layer with the well region pattern as a mask; and
removing the photoresist layer with the well region pattern.
